(19) United States
(12) Patent Application Publication
(10) Pub. No.: US 2005/0263483 A1
(43) Pub. Date: Dec. 1, 2005

(54) Modifying the viscosity of etchants

(76) Inventors: Justin K. Brask, Portland, OR (US); Jack Kavalieros, Portland, OR (US); Mark L. Doczy, Beaverton, OR (US); Matthew Metz, Hillsboro, OR (US); Suman Datta, Beaverton, OR (US); Uday Shah, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 11/196,034

(22) Filed: Aug. 3, 2005

Related U.S. Application Data
(62) Division of application No. 10/816,539, filed on Apr. 1, 2004.

(51) Int. Cl. B44C 1/22; C09K 13/00; H01L 21/302

(52) U.S. Cl. 216/41; 216/83; 438/745; 252/79.1

(57) ABSTRACT

Semiconductor integrated circuit structures, such as stacks containing metal layers, may be etched with a modified viscosity etchant. An increased viscosity etchant, for example, may reduce undercutting when a metal film is being etched.

### BACKGROUND

This invention relates generally to the formation of semiconductor integrated circuits.

In integrated circuit fabrication, device features are defined using etching processes. The etching processes may be utilized to form desired features such as holes and other shapes. Generally, a mask is applied, the mask is patterned and a desired arrangement is etched using the patterned mask.

One problem with traditional wet etching is that when etching one layer, undercutting under the masking layers may occur. Because the etchant has an isotropic character to it, it etches both downwardly and laterally. Undercutting the mask may be undesirable, for example, when patterning of metal containing stacks.

Another problem with existing etchants is that, once applied, the etchant tends to spread on the applied surface. Therefore, it is not possible to precisely control the extent of lateral distribution of the etchant.

Thus, there is a need for alternate ways to etch materials in semiconductor integrated circuit fabrication processes.

### BRIEF DESCRIPTION OF THE DRAWINGS

FIG. 1 is an enlarged, cross-sectional view of one embodiment of the present invention at an early stage;

FIG. 2 is an enlarged, cross-sectional view corresponding to FIG. 1 at a subsequent stage; and

FIG. 3 is a flow chart for one embodiment of the present invention.

### DETAILED DESCRIPTION

By increasing the viscosity of a wet etchant, undercutting may be reduced. In addition, increased viscosity may enable the control of the lateral distribution of the etchant on the surface to be etched. Conversely, decreasing the viscosity may increase isotropic etching.

Viscosity may be altered any number of ways, including adding thickening agents to the etchant to increase viscosity or diluents to decrease viscosity. For example, glycol or glycerol may be added to conventional etchants such as sulfuric acid, hydrofluoric acid, or acetic acid, to name a few examples. As another example, an existing etchant may be dehydrated to make the resulting etchant more viscous.

The extent of viscosity may be tunable by controlling the dehydration or the amount of viscous material that is added or controlling the viscosity of the material that is added. In one embodiment of the present invention, the viscosity may be in the range of one to twenty centipoise for etching stacked film thicknesses ranging from 10 to 200 Angstroms.

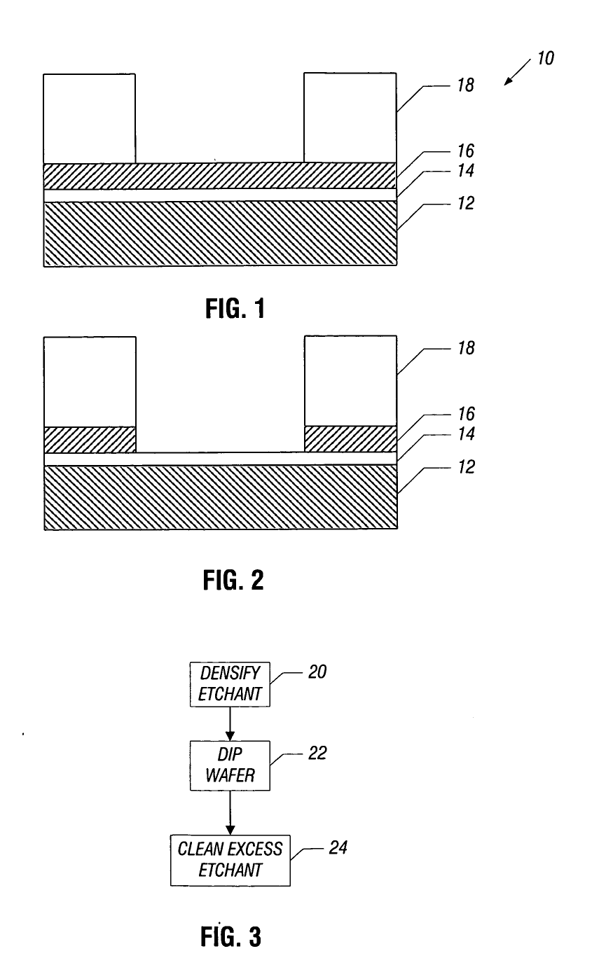

Referring to FIG. 1, a metal stack 10 may be formed of a semiconductor wafer 12, covered by a gate dielectric material 14. The gate dielectric 14 may be covered by a thin metal film 16 to be etched. In one embodiment, the thin metal film 16 may ultimately become a metal gate of a field effect transistor. A polysilicon mask 18 may be defined with an aperture 26. The aperture 26 determines the region of the film 16 that will be etched.

The viscous etchant may be applied to the metal film 16. In one embodiment, a bath of the etchant may be prepared, for example, by dehydrating an etchant such as sulfuric acid or adding an appropriate thickening agent to the bath. Then the wafer 12 may be dipped in the bath to etch the layer 16 as shown in FIG. 2. The amount of undercutting may be reduced by tailoring the viscosity of the wet etchant to be too great to undercut the metal film layer 16 in a given stack 10.

In one example, a solution of sulfuric acid (about 37 percent in water) was spiked with one tenth of an equivalent of hydrogen peroxide (30 percent concentration in water) and the mixture (which spontaneously heated to about 140° C. upon mixing) was held at 126 degrees C. for 3 hours until most of the water had been boiled off, leaving a solution of about 90 percent sulfuric acid. The remaining 10 percent is water held in the sulfuric matrix and some remaining hydrogen peroxide. This solution was cooled to room temp (24° C.) by circulating the solution through a chiller. This mixture was then applied to a metal film 16 in the form of a 50 Angstrom titanium nitride film, eliminating undercutting which occurs if viscosity was not increased.

Referring to FIG. 3, the process flow then involves densifying the etchant as indicated in block 20. Once the etchant has been densified, in one embodiment, the wafer with the layer to be etched is simply dipped into a bath of the densified etchant as indicated in block 22. Then any excess material may be cleaned from the etchant as indicated in block 24. In some cases, repeated cleans may be necessary to remove the increased viscosity etchant.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1-7. (canceled)

8. A method comprising:
increasing the viscosity of a wet etchant to reduce underetching of a dielectric under a metal layer by dehydrating the etchant to reduce the amount of undercutting of an etched layer; and
etching the metal layer over the dielectric.

9. (canceled)

10. The method of claim 8 including increasing the viscosity of the etchant by adding a thickening agent to said etchant.

11. The method of claim 8 including applying said increased viscosity wet etchant to a semiconductor wafer to etch a layer on said wafer.

12-21. (canceled)
